(19) United States
(12) Patent Application Publication
(10) Pub. No.: US 2011/0313184 A1
(43) Pub. Date: Dec. 22, 2011

(54) INSULATING FILM MATERIAL, AND FILM FORMATION METHOD UTILIZING THE MATERIAL, AND INSULATING FILM

(76) Inventors: Nobuo Tajima, Tsukuba-shi (JP); Shuji Nagano, Tsuchiura-shi (JP); Yoshiaki Inaishi, Tsuchiura-shi (JP); Hideharu Shimizu, Tsukuba-shi (JP); Yoshi Ohashi, Tsukuba-shi (JP); Takeshi Kada, Uenohara-shi (JP); Shigeki Matsumoto, Uenohara-shi (JP); Yong hua Xu, Uenohara-shi (JP)

(21) Appl. No.: 13/147,719

(22) PCT Filed: Feb. 5, 2010
(86) PCT No.: PCT/JP2010/000704

§ 371 Date: Aug. 3, 2011

(30) Foreign Application Priority Data
Feb. 6, 2009 (JP) 2009-026122
Jul. 30, 2009 (JP) 2009-178360

(51) Int. Cl. C07F 7/08; C23C 16/30; C23C 16/56; C07F 7/18

(52) U.S. Cl. 556/406; 556/465; 556/483; 556/486; 556/482; 556/489; 427/578; 427/558

(57) ABSTRACT

An insulating film material for plasma CVD of the present invention is constituted of a silicon compound including two hydrocarbon groups bonded to each other to form a ring structure together with a silicon atom, or at least one branched hydrocarbon group, wherein within the branched hydrocarbon group, α-carbon that is a carbon atom bonded to the silicon atom constitutes a methylene group, and β-carbon that is a carbon atom bonded to the methylene group or γ-carbon that is a carbon atom bonded to the β-carbon is a branching point.

### TECHNICAL FIELD

The present invention relates to an insulating film material that is useful as an interlayer insulating film or the like in a semiconductor device, and also relates to a film formation method and an insulating film that use the insulating film material. According to the present invention, an insulating film having a low dielectric constant as well as plasma resistance can be obtained.

Priority is claimed on Japanese Patent Application No. 2009-026122, filed Feb. 6, 2009, and Japanese Patent Application No. 2009-178360, filed Jul. 30, 2009, the contents of which are incorporated herein by reference.

### BACKGROUND ART

As the levels of integration within semiconductor devices increase, the wiring layers continue to become increasingly miniaturized. However, in these very fine wiring layers, the effects of signal delays within the wiring layer tend to increase, impeding increases in the signal transmission speed. These signal delays are proportional to the resistance of the wiring layer and the capacity between wiring layers, and therefore in order to achieve higher transmission speeds, the resistance of the wiring layers and the capacity between wiring layers must be reduced.

Accordingly, in recent years there has been a change in the materials used in forming the wiring layers, from the more conventional aluminum to low resistivity copper, whereas interlayer insulating films having a low relative dielectric constant are now being used to reduce the capacity between wiring layers.

For example, a SiO₂ film has a relative dielectric constant of 4.1 and a SiOF film has a relative dielectric constant of 3.7, but recently, SiOCH films and organic films having even lower relative dielectric constant are starting to be used.

Further, in the process of forming a multilayer wiring structure, treatments such as an etching step, a washing step and a polishing step are conducted on the insulating film. In order to prevent the insulating film to be damaged during these treatments, the insulating film is required to have a high mechanical strength (for example, refer to Patent Document 1).

Trimethylsilane, dimethyldimethoxysilane (DMDMOS), octamethylcyclotetrasiloxane (OMCTS) and trimethylcyclosiloxane (TMCAT (registered trademark)) are used in the formation of an insulating film by the chemical vapor deposition (CVD) method. In recent years, a method has also been examined, in which a hydrocarbon compound is incorporated within an insulating film by mixing the hydrocarbon compound with the above-mentioned insulating film material, followed by ultraviolet irradiation to remove the hydrocarbon from the insulating film while forming voids within the insulating film, thereby further reducing the relative dielectric constant.

On the other hand, low mechanical strength during the mechanical processing, such as a chemical mechanical polishing (CMP) process, has been pointed out as a problem for the insulating film where the voids have been formed.

Further, as the miniaturization of semiconductor devices continues to progress, poor plasma resistance during the plasma processes such as an etching process or an asking process has also become a crucial problem (for example, refer to Non-Patent Document 1).

### CITATION LIST

### Patent Document

[Patent Document 1] WO 2006/075578

### Non-Patent Document

[Non-Patent Document 1] Proceedings of ADMETA 2008, 2008, pp. 34-35

### SUMMARY OF INVENTION

### Technical Problem

However, the insulating films formed from trimethylsilane, OMCTS and TMCAT disclosed in the aforementioned prior-art documents exhibited high relative dielectric constant of about 3.8 to about 4.0 following the plasma processes, and also the plasma resistance thereof was not necessarily superior to that of the conventional SiOCH insulating films.

Accordingly, an object of the present invention is to obtain an insulating film having a high plasma resistance as well as a low relative dielectric constant.

### Solution to Problem

In order to solve such problems,

a first aspect of the present invention is an insulating film material for plasma CVD which is constituted of a silicon compound including two hydrocarbon groups bonded to each other to form a ring structure together with a silicon atom, or at least one branched hydrocarbon group,

wherein within the branched hydrocarbon group, α-carbon that is a carbon atom bonded to the silicon atom constitutes a methylene group, and β-carbon that is a carbon atom bonded to the methylene group or γ-carbon that is a carbon atom bonded to the β-carbon is a branching point.

In the first aspect of the present invention, the branched hydrocarbon group is preferably an i-butyl group, an i-pentyl group, a neopentyl group or a neohexyl group.

In addition, the silicon compound is preferably a compound represented by a chemical formula (1) shown below which includes an i-butyl group, an i-pentyl group, a neopentyl group or a neohexyl group, and also includes an oxygen atom.

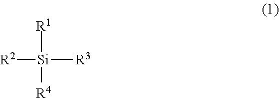

In the chemical formula (1), each of R¹ to R⁴ represents any one of moieties selected from the group consisting of H, CₙH₂ₙ₊₁, CₖH₂ₖ₋₁, CₗH₂ₗ₋₃, OCₙH₂ₙ₊₁, OCₖH₂ₖ₋₁ and OCₗH₂ₗ₋₃, n represents an integer of 1 to 5, and k and l represent an integer of 2 to 6; with the proviso that any two of R¹ to R⁴ represents any one of moieties selected from the group consisting of CH₂CH(CH₃)CH₃, CH₂CH(CH₃)CH₂CH₃, CH₂CH₂CH(CH₃)CH₃, CH₂C(CH₃)₂CH₃ and CH₂CH₂C(CH₃)₂CH₃, and any one of OCH₃ and OC₂H₅.

In addition, the silicon compound is preferably a compound represented by a chemical formula (2) or a chemical formula (3) shown below which includes an i-butyl group, an i-pentyl group, a neopentyl group or a neohexyl group, and includes no oxygen atom.

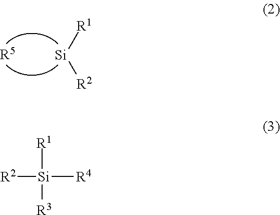

In the chemical formula (2) and chemical formula (3), each of R¹ to R⁴ represents any one of moieties selected from the group consisting of H, CₙH₂ₙ₊₁, CₖH₂ₖ₋₁, and CₗH₂ₗ₋₃, R⁵ represents CₓH₂ₓ, n represents an integer of 1 to 5, k and l represent an integer of 2 to 6, and x represents an integer of 3 to 7; with the proviso that any one of R¹ to R⁴ represents any one of moieties selected from the group consisting of CH₂CH(CH₃)CH₃, CH₂CH(CH₃)CH₂CH₃, CH₂CH₂CH(CH₃)CH₃, CH₂C(CH₃)₂CH₃ and CH₂CH₂C(CH₃)₂CH₃.

In addition, the silicon compound is preferably a compound represented by a chemical formula (4) or a chemical formula (5) shown below which includes no oxygen atom.

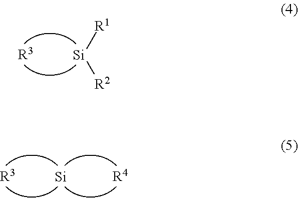

In the chemical formula (4) and chemical formula (5), each of R¹ to R² represents any one of moieties selected from the group consisting of H, CₙH₂ₙ₊₁, CₖH₂ₖ₋₁ and CₗH₂ₗ₋₃, R³ to R⁴ represent CₓH₂ₓ, n represents an integer of 1 to 5, k and l represent an integer of 2 to 6, and x represents an integer of 3 to 7.

A second aspect of the present invention is an insulating film material for plasma CVD which is constituted of a silicon compound including an i-butyl group or a n-propyl group.

In the second aspect of the present invention, the silicon compound is preferably a compound represented by a chemical formula (6) shown below which includes an i-butyl group or a n-propyl group, and also includes an oxygen atom.

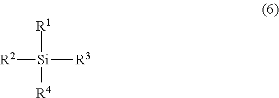

In the chemical formula (6), each of R¹ to R⁴ represents any one of moieties selected from the group consisting of H, CₙH₂ₙ₊₁, CₖH₂ₖ₋₁, CₗH₂ₗ₋₃, OCₙH₂ₙ₊₁, OCₖH₂ₖ₋₁ and OCₗH₂ₗ₋₃, n represents an integer of 1 to 5, and k and l represent an integer of 2 to 6; with the proviso that any three of R¹ to R⁴ represents any one of moieties selected from the group consisting of H, CH₃, CH₂CH₃, CH₂CH₂CH₃, CH₂CH(CH₃)CH₃, CH₂CH(CH₃)C₂H₅, CH₂CH₂CH(CH₃)CH₃, CH₂C(CH₃)₂CH₃ and CH₂CH₂C(CH₃)₂CH₃, any one of OCH₃ and OC₂H₅, and any one of an i-butyl group and a n-propyl group.

In addition, the silicon compound is preferably a compound represented by a chemical formula (7) shown below, which includes an i-butyl group or a n-propyl group, and includes no oxygen atom.

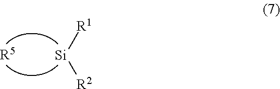

In the chemical formula (7), each of R¹, R² and R⁵ represents any one of moieties selected from the group consisting of H, CₘH₂ₘ, CₙH₂ₙ₊₁, CₖH₂ₖ₋₁ and CₗH₂ₗ₋₃, n and m represent an integer of 1 to 5, and k and l represent an integer of 2 to 6; with the proviso that R¹ and R² represents any one of moieties selected from the group consisting of H, CH₃, CH₂CH₃, CH₂CH₂CH₃, CH₂CH(CH₃)CH₃, CH₂CH(CH₃)C₂H₅, CH₂CH₂CH(CH₃)CH₃, CH₂C(CH₃)₂CH₃ and CH₂CH₂C(CH₃)₂CH₃, and any one of an i-butyl group and a n-propyl group, and R⁵ represents any one of (CH₂)₃, (CH₂)₄ and (CH₂)₅.

In addition, the silicon compound is preferably a compound represented by a chemical formula (8) shown below, which includes an i-butyl group or a n-propyl group, and includes no oxygen atom.

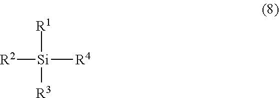

In the chemical formula (8), each of R¹ to R⁴ represents any one of moieties selected from the group consisting of H, CₙH₂ₙ, CₙH₂ₙ₊₁, CₖH₂ₖ₋₁ and CₗH₂ₗ₋₃, n represents an integer of 1 to 5, and k and l represent an integer of 2 to 6; with the proviso that any two of R¹ to R⁴ represents any one of moieties selected from the group consisting of H, CH₃, CH₂CH₃, CH₂CH₂CH₃, CH₂CH(CH₃)CH₃, CH₂CH(CH₃)C₂H₅, CH₂CH₂CH(CH₃)CH₃, CH₂C(CH₃)₂CH₃ and CH₂CH₂C(CH₃)₂CH₃, and any one of an i-butyl group and a n-propyl group.

In addition, the silicon compound is preferably a compound represented by a chemical formula (9) shown below, which includes an i-butyl group or a n-propyl group, and also includes an oxygen atom.

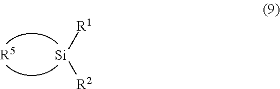

In the chemical formula (9), R¹ and R² represent any one of OCH₃ and OC₂H₅, and any one of an i-butyl group and a n-propyl group, and R⁵ represents any one of (CH₂)₃, (CH₂)₄ and (CH₂)₅,

Further, the insulating film material for plasma CVD preferably has a boiling point at 1 atmospheric pressure of 300° C. or less.

A third aspect of the present invention is a film formation method that includes a step of forming an insulating film by the plasma CVD method using the insulating film material for plasma CVD according to the present invention or a mixed gas of this insulating film material for plasma CVD and an oxidizing gas.

In the third aspect of the present invention, it is preferable to further include a step of subjecting the insulating film to ultraviolet irradiation.

In addition, the oxidizing gas is preferably an oxygen-containing compound. Further, the film forming temperature is preferably from 150° C. to 250° C.

A fourth aspect of the present invention is an insulating film obtained by the film formation method according to the present invention.

### Advantageous Effects of Invention

According to the present invention, since an insulating film is formed by using the silicon compound represented by the aforementioned chemical formulas (1) to (9) or a mixed gas of this silicon compound and an oxidizing gas as an insulating film material, film-forming by the plasma CVD method, followed by an ultraviolet irradiation treatment, an insulating film exhibiting a low dielectric constant as well as high levels of mechanical strength and plasma resistance can be obtained.

### BRIEF DESCRIPTION OF DRAWINGS

FIG. 1 is a schematic block diagram showing one example of a film forming apparatus used in the present invention.

FIG. 2 is a schematic block diagram showing one example of an ultraviolet irradiation apparatus used in the present invention.

FIG. 3 is a graph used for the evaluation of plasma resistance which shows an infrared absorption spectrum of an insulating film before ultraviolet irradiation and an infrared absorption spectrum of an insulating film after ultraviolet irradiation.

FIG. 4 is a diagram showing an infrared absorption spectrum of an insulating film after ultraviolet irradiation in Example 1.

FIG. 5 is a diagram showing an infrared absorption spectrum of an insulating film after ultraviolet irradiation in Example 2.

FIG. 6 is a diagram showing an infrared absorption spectrum of an insulating film after ultraviolet irradiation n Example 3.

FIG. 7 is a diagram showing an infrared absorption spectrum of an insulating film after ultraviolet irradiation in Comparative Example 1.

FIG. 8 is a diagram showing an infrared absorption spectrum of an insulating film after ultraviolet irradiation in Comparative Example 2.

### DESCRIPTION OF EMBODIMENTS

The present invention will be described below in detail.

An insulating film material for plasma CVD according to the present invention is constituted of a silicon compound represented by the aforementioned chemical formulas (1) to (9). All of these silicon compounds are known compounds and can be obtained through known synthesis methods. However, use of these compounds represented by the chemical formulas (1) to (9) as an insulating film has not been known conventionally.

Specific examples of preferred compounds represented by the chemical formula (1) include isobutyldimethylmethoxysilane, isopentyldimethylmethoxysilane, neopentyldimethylmethoxysilane, neohexyldimethylmethoxysilane and diisobutyldimethoxysilane.

Examples of other silicon compounds to be used include isobutylmethoxysilane, isobutylmethylmethoxysilane, isobutylethylmethoxysilane, isobutylpropylmethoxysilane, isobutylbutylmethoxysilane, isobutyl tertiary butylmethoxysilane, isobutylpentylmethoxysilane, isobutyl secondary butylmethoxysilane, isobutylisopentylmethoxysilane, isobutylneopentylmethoxysilane, isobutyl tertiary pentylmethoxysilane, isobutyldiethylmethoxysilane, isobutyldipropylmethoxysilane, isobutyldibutylmethoxysilane, isobutyl ditertiary butylmethoxysilane, isobutyldipentylmethoxysilane, isobutyl disecondary butylmethoxysilane, isobutyldiisopentylmethoxysilane, isobutyldineopentylmethoxysilane, isobutyl ditertiary pentylmethoxysilane, isobutyltrimethoxysilane, triisobutylmethoxysilane, diisobutylmethoxysilane, isobutyldimethoxysilane, isobutylmethoxyethoxysilane, isobutylmethoxypropoxysilane, isobutylmethoxybutoxysilane, isobutylmethoxypentoxysilane, diisobutyl ethoxyethoxysilane, diisobutylmethoxypropoxysilane, diisobutylmethoxybutoxysilane, diisobutylmethoxypentoxysilane, isobutyldimethoxyethoxysilane, isobutyldimethoxypropoxysilane, isobutyldimethoxybutoxysilane, isobutyldimethoxypentoxysilane, isobutyldimethoxyethoxysilane, isobutyldimethoxypropoxysilane, isobutylmethoxydibutoxysilane, isobutylmethoxydipentoxysilane, tertiary butylmethoxysilane, tertiary butylmethylmethoxysilane, tertiary butylethylmethoxysilane, tertiary butylpropylmethoxysilane, tertiary butylbutylmethoxysilane, tertiary butylpentylmethoxysilane, tertiary butyl secondary butylmethoxysilane, tertiary butylisopentylmethoxysilane, tertiary butylneopentylmethoxysilane, tertiary butyl tertiary pentylmethoxysilane, tertiary butyldiethylmethoxysilane, tertiary butyldipropylmethoxysilane, tertiary butyldibutylmethoxysilane, tritertiary butylmethoxysilane, tertiary butyldipentylmethoxysilane, tertiary butyl disecondary butylmethoxysilane, tertiary butyldiisopentylmethoxysilane, tertiary butyldineopentylmethoxysilane, tertiary butyl ditertiary pentylmethoxysilane, tertiary butyltrimethoxysilane, ditertiary butylmethoxysilane, tertiary butyldimethoxysilane, tertiary butylmethoxyethoxysilane, tertiary butylmethoxypropoxysilane, tertiary butylmethoxybutoxysilane, tertiary butylmethoxypentoxysilane, diisobutylmethoxyethoxysilane, ditertiary butylmethoxypropoxysilane, ditertiary butylmethoxybutoxysilane, ditertiary butylmethoxypentoxysilane, tertiary butyldimethoxyethoxysilane, tertiary butyldimethoxypropoxysilane, tertiary butyldimethoxybutoxysilane, tertiary butyldimethoxypentoxysilane, tertiary butyldimethoxyethoxysilane, tertiary butyldimethoxypropoxysilane, tertiary butylmethoxydibutoxysilane and isobutylmethoxydipentoxysilane.

Specific examples of preferred compounds represented by the chemical formula (2) include 1-1-diisobutyl-1-silacyclopentane.

Examples of other silicon compounds to be used include 1-isobutyl-1-silacyclopropane, 1-isobutyl-1-silacyclobutane, 1-isobutyl-1-silacyclopentane, 1-isobutyl-1-methyl-1-silacyclopropane, 1-isobutyl-1-methyl-1-silacyclobutane, 1-isobutyl-1-ethyl-1-silacyclopentane, 1-isobutyl-1-butyl-1-silacyclopropane, 1-isobutyl-1-butyl-1-silacyclobutane, 1-isobutyl-1-butyl-1-silacyclopentane, 1-isobutyl-1-pentyl-1-silacyclopropane, 1-isobutyl-1-pentyl-1-silacyclobutane, 1-isobutyl-1-pentyl-1-silacyclopentane, 1-isobutyl-1-tertiarybutyl-1-silacyclopropane, 1-isobutyl-1-tertiary butyl-1-silacyclobutane, 1-isobutyl-1tertiary butyl-1-silacyclopentane, 1-1-diisobutyl-1-silacyclopropane, 1-1-diisobutyl-1-silacyclobutane, 1-1-diisobutyl-1-silacyclopentane, 1-1-ditertiarybutyl-1-silacyclopropane, 1-1-ditertiarybutyl-1-silacyclobutane, 1-1-ditertiarybutyl-1-silacyclopentane, 1-1-dipropyl-1-silacyclopropane, 1-1-dipropyl-1-silacyclobutane and 1-1-dipropyl-1-silacyclopentane.

Specific examples of preferred compounds represented by the chemical formula (3) include isobutyltrimethylsilane, diisobutyldimethylsilane, diisobutylsilane, diisobutylmethylsilane, diisobutylethylsilane, diisobutylethylmethylsilane, diisobutyldiethylsilane, isopentyltrimethylsilane, neopentyltrimethylsilane and neohexyltrimethylsilane.

Examples of other silicon compounds to be used include isobutyltriethylsilane, isobutyltripropylsilane, isobutyltributylsilane, tetraisobutylsilane, isobutyl secondary butylsilane, isobutyltripentylsilane, isobutylisopentylsilane, isobutylneopentylsilane, isobutyl tertiary pentylsilane, diisobutyldiethylsilane, diisobutyldipropylsilane, diisobutyldibutylsilane, diisobutyl secondary butylsilane, diisobutyldipentylsilane, diisobutylisopentylsilane, diisobutylneopentylsilane, diisobutyl tertiary pentylsilane, triisobutylethylsilane, triisobutylpropylsilane, triisobutylbutylsilane, triisobutyl secondary butylsilane, triisobutylpentylsilane, triisobutylisopentylsilane, triisobutylneopentylsilane, triisobutyl tertiary pentylsilane, isobutyldiethylsilane, isobutyldipropylsilane, isobutyldibutylsilane, isobutyl disecondary butylsilane, isobutyldiisopentylsilane, isobutyldineopentylsilanc, isobutyl ditertiary pentylsilane, tertiary butyltriethylsilane, tertiary butyltripropylsilane, tertiary butyltributylsilane, tetratertiary butylsilane, tertiary butyl secondary butylsilane, tertiary butyltripentylsilane, tertiary butylisopentylsilane, tertiary butylneopentylsilane, tertiary butyl tertiary pentylsilane, ditertiary butyldiethylsilane, ditertiary butyldipropylsilane, ditertiary butyldibutylsilane, ditertiary butyl secondary butylsilane, ditertiary butyldipentylsilane, ditertiary butylisopentylsilane, ditertiary butylneopentylsilane, ditertiary butyl tertiary pentylsilane, tritertiary butylethylsilane, tritertiary butylpropylsilane, tritertiary butylbutylsilane, tritertiary butyl secondary butylsilane, tritertiary butylpentylsilane, tritertiary butylisopentylsilane, tritertiary butylneopentylsilane, tritertiary butyl tertiary pentylsilane, tertiary butyldiethylsilane, tertiary butyldipropylsilane, tertiary butyldibutylsilane, tertiary butyl disecondary butylsilane, tertiary butyldiisopentylsilane, tertiary butyldineopentylsilane, tertiary butyl ditertiary pentylsilane, propyltriethylsilane, tetrapropylsilane, propyltributylsilane, tetrapropylsilane, propyl secondary butylsilane, propyltripentylsilane, propylisopentylsilane, propylneopentylsilane, propyl tertiary pentylsilane, dipropyldiethylsilane, dipropyldipropylsilane, dipropyldibutylsilane, dipropyl secondary butylsilane, dipropyldipentylsilane, dipropylisopentylsilane, dipropylneopentylsilane, dipropyl tertiary pentylsilane, tripropylethylsilane, tetrapropylsilane, tripropylbutylsilane, tripropyl secondary butylsilane, tripropylpentylsilane, tripropylisopentylsilane, tripropylneopentylsilanc, tripropyl tertiary pentylsilane, propyldiethylsilane, propyldipropylsilane, propyldibutylsilane, propyl disecondary butylsilane, propyldiisopentylsilane, propyldineopentylsilane and propyl ditertiary pentylsilane.

Specific examples of preferred compounds represented by the chemical formula (4) include 1-1-divinyl-1-silacyclopentane.

Examples of other silicon compounds to be used include 1-1-diallyl-1-silacyclopentane, 1-1-diethyl-1-silacyclopentane, 1-1-dipropyl-1-silacyclopentane, 1-1-dibutyl-1-silacyclopentane, 1-1-diisobutyl-1-silacyclopentane, 1-1-ditertiary butyl-1-silacyclopentane, 1-1-diisopentyl-1-silacyclopentane, 1-1-dipentyl-1-silacyclopentane, 1-1-dineopentyl-1-silacyclopentane and 1-1-ditertiary pentyl-1-silacyclopentane.

Specific examples of preferred compounds represented by the chemical formula (5) include 5-silaspiro[4,4]nonane.

Examples of other silicon compounds to be used include 4-silaspiro[3,3]heptane and 3-silaspiro[2,2]pentane.

Specific examples of preferred compounds represented by the chemical formula (6) include tripropylmethoxysilane (TPMOS).

Examples of other silicon compounds to be used include propylmethoxysilane, propylmethylmethoxysilane, propylethylmethoxysilane, dipropylmethoxysilane, dipropylmethylmethoxysilane, dipropylethylmethoxysilane, propyldimethoxysilane, propylmethyldimethoxysilane, propylethyldimethoxysilane, dipropyldimethoxysilane, propyltrimethoxysilane, propylethoxysilane, propylmethylethoxysilane, propylethylethoxysilane, dipropylethoxysilane, dipropylmethylethoxysilane, dipropylethylethoxysilane, propyldiethoxysilane, propylmethyldiethoxysilane, propylethyldiethoxysilane, dipropyldiethoxysilane, propyltriethoxysilane, tripropylethoxysilane, diisobutylmethylmethoxysilane, diisobutylpropylmethoxysilane, diisobutylmethylethoxysilane and diisobutylpropylethoxysilane.

Of these, a compound having at least one methoxy group or ethoxy group such as tripropylmethoxysilane is preferred. Examples of particularly preferred compounds include a compound having one methoxy group or ethoxy group within the molecular structure, such as propylmethoxysilane, propylmethylmethoxysilane, propylethylmethoxysilane, dipropylmethoxysilane, dipropylmethylmethoxysilane, dipropylethylmethoxysilane, propylethoxysilane, propylmethylethoxysilane, propylethylethoxysilane, dipropylethoxysilane, dipropylmethylethoxysilane, dipropylethylethoxysilane and tripropylethoxysilane.

Specific examples of preferred compounds represented by the chemical formula (7) include 1-1-dipropyl-1-silacyclopentane.

Examples of other silicon compounds to be used include 1-isobutyl-1-propyl-1-silacyclopropane, 1-isobutyl-1-propyl-1-silacyclohexane, 1-1-dipropyl-1-silacyclobutane and 1-1-dipropyl-1-silacyclohexane.

Specific examples of preferred compounds represented by the chemical formula (8) include propyltrimethylsilane and dipropyldimethylsilane.

Examples of other silicon compounds to be used include diisobutyldipropylsilane, triisobutylpropylsilane, isobutyldipropylsilane, tertiary butyltripropylsilane, ditertiary butyldipropylsilane, tritertiary butylpropylsilane, tertiary butyldipropylsilane, propyltriethylsilane, tetrapropylsilane, propyltributylsilane, tetrapropylsilane, propyl secondary butylsilane, propyltripentylsilane, propylisopentylsilane, propylneopentylsilane, propyl tertiary pentylsilane, dipropyldiethylsilane, dipropyldipropylsilane, dipropyldibutylsilane, dipropyl secondary butylsilane, dipropyldipentylsilane, dipropylisopentylsilane, dipropylneopentylsilane, dipropyl tertiary pentylsilane, tripropylethylsilane, tetrapropylsilane, tripropylbutylsilane, tripropyl secondary butylsilane, tripropylpentylsilane, tripropylisopentylsilane, tripropylneopentylsilane, tripropyl tertiary pentylsilane, propyldiethylsilane, propyldipropylsilane, propyldibutylsilane, propyl disecondary butylsilane, propyldiisopentylsilane, propyldineopentylsilane and propyl ditertiary pentylsilane.

Specific examples of preferred compounds represented by the chemical formula (9) include isobutylmethoxysilacyclohexane and isobutylmethoxysilacyclohexane.

Examples of other silicon compounds to be used include propylethoxysilacyclohexane and propylethoxysilacyclopentane.

Next, the film formation method of the present invention will be described.

In the film formation method of the present invention, film formation is basically conducted by the plasma CVD method using the insulating film, material represented by the chemical formulas (1) to (9) mentioned above. In this case, one type of the silicon compounds represented by the chemical formulas (1) to (9) can be used alone, or two or more types thereof can be mixed for use.

When one or more types of insulating film materials are mixed and used, the mixing ratio is not particularly limited and can be determined in consideration of the relative dielectric constant or plasma resistance of the obtained insulating film, or the like.

In addition, during film formation, an oxidizing gas may be entrained with the insulating film material constituted from the silicon compounds represented by the aforementioned chemical formulas (1) to (9) to form a film, or a film may be formed without entraining an oxidizing gas. These combinations can be appropriately selected in consideration of the properties (such as the plasma resistance) of the obtained insulating film.

More specifically, during film formation, in those cases where the insulating film material constituted of the silicon compounds represented by the aforementioned chemical formulas (2), (5), (7) and (8) is used, an oxidizing gas is added to form a film. On the other hand, in those cases where the insulating film material constituted of the silicon compounds represented by the aforementioned chemical formulas (1), (6) and (9) is used, it is desirable to form a film by this insulating film material alone for the sake of improving plasma resistance.

This oxidizing gas is not particularly limited, although examples thereof include a gas containing oxygen atoms, such as oxygen gas, carbon dioxide and tetraethoxysilane (TEOS). Two or more types of oxidizing gases can be mixed for use, and their mixing ratio and the mixing ratio with the insulating film material are not particularly limited.

Accordingly, a film forming gas fed to the inside of a chamber within a film forming apparatus for film formation may be, at times, a mixed gas where an oxidizing gas is mixed in addition to the insulating film material gas.

By using an oxidizing agent concomitantly during film formation that uses the silicon compounds with no oxygen atom represented by the aforementioned chemical formulas (2), (5), (7) and (8), a SiOCH film with high plasma resistance can be formed, as in the case of film fou nation that uses the silicon compounds represented by the aforementioned chemical formulas (1), (6) and (9).

If the insulating film material and the oxidizing gas are gaseous at normal temperatures, they may be used as they are. But if they are liquid, gasification is performed prior to use, and this gasification may be achieved by conducting bubbling with an inert gas such as helium, using a vaporizer, or by conducting heating.

These insulating film materials and the oxidizing gas preferably have a boiling point at 1 atmospheric pressure of 300° C. or less.

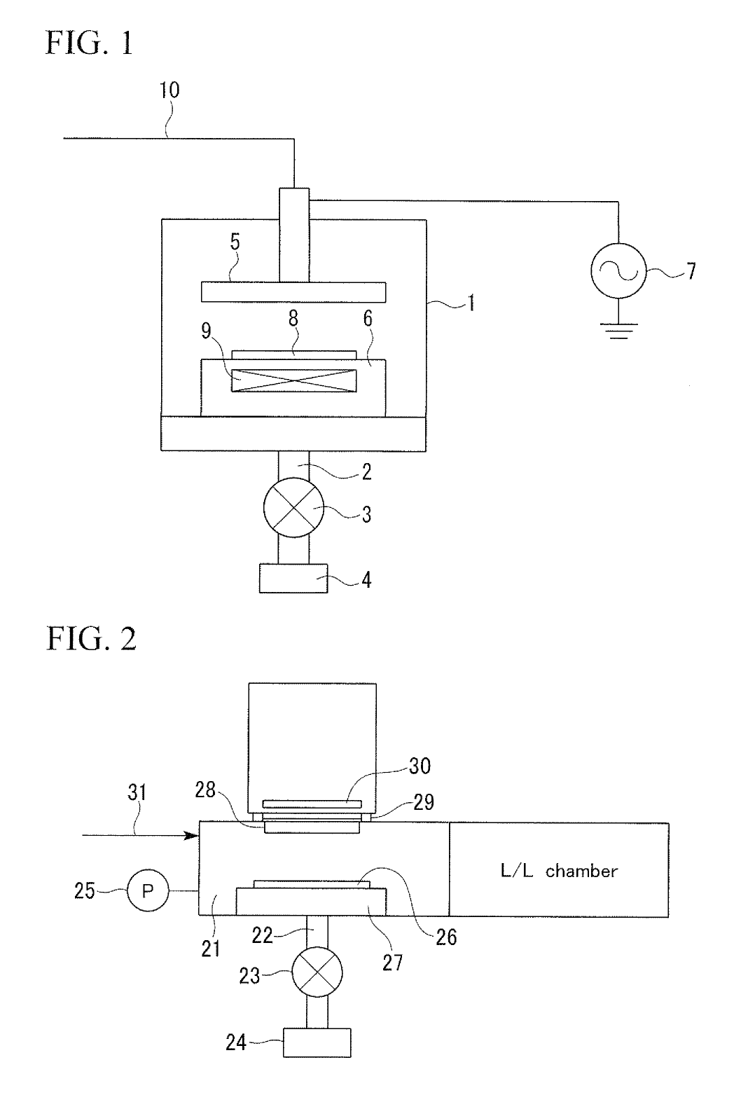

The plasma CVD method may employ a conventional method, and for example, film formation may be conducted using a parallel plate-type plasma film formation apparatus such as that shown in FIG. 1.

The plasma film formation apparatus shown in FIG. 1 includes a chamber 1 that is able to be placed under reduced pressure, and this chamber 1 is connected to an exhaust pump 4 via an exhaust pipe 2 and an on-off valve 3. In addition, although not shown in the drawing, the chamber 1 is also equipped with a pressure gauge, which enables the pressure inside the chamber 1 to be measured. A pair of flat plate-shaped electrodes, namely an upper electrode 5 and a lower electrode 6, is provided in a mutually opposing arrangement inside the chamber 1. The upper electrode 5 is connected to a high-frequency power source 7, so that a high-frequency electric current can be applied to the upper electrode 5.

The lower electrode 6 also functions as a mount for mounting a substrate 8, and a heater 9 is also provided inside thereof, enabling the substrate 8 to be heated.

In addition, a gas supply pipe 10 is connected to the upper electrode 5. A film formation gas supply source that is not shown in the drawing is connected to this gas supply pipe 10, and the film formation gas is supplied from this film formation gas supply apparatus. In addition, this film formation gas passes through a plurality of through voids formed within the upper electrode 5 and diffuses out and flows towards the lower electrode 6.

In addition, the film formation gas supply source is equipped with a vaporizer for vaporizing the aforementioned insulating film material and a flow rate regulating valve for regulating the flow rate of the insulating film material, and is also provided with a supply device for supplying the oxidizing gas. Such gas also flows through the gas supply pipe 10 and flows into the chamber 1 from the upper electrode 5.

The substrate 8 is placed on top of the lower electrode 6 inside the chamber 1 of the plasma film formation apparatus, and the film formation gas described above is fed from the film formation gas supply source into the chamber 1. A high-frequency electric current is applied to the upper electrode 5 from the high-frequency power source 7, generating a plasma inside the chamber 1. As a result, an insulating film produced by a gas phase chemical reaction of the film formation gas described above is formed on top of the substrate 8.

The substrate 8 is mainly formed from a silicon wafer. Other insulating films, conductive films or wiring structures or the like which have been formed in advance may be present on top of this silicon wafer.

In the plasma CVD method, an ICP plasma, ECR plasma, magnetron plasma, high-frequency plasma, microwave plasma, capacitively coupled plasma (parallel plate-type), inductively coupled plasma or the like can be used. A two frequency excitation plasma in which a high-frequency is also supplied to the lower electrode of a parallel plate-type apparatus may also be used.

Preferred ranges for the film formation conditions within this plasma film formation apparatus are indicated below, although the conditions are not necessarily restricted to these ranges.

Insulating film material flow rate: 5 to 200 cc/minute (in the case of two or more materials, this range applies to the total flow rate)

Oxidizing gas flow rate: 0 to 200 cc/minute

Pressure: 1 Pa to 5,000 Pa

RF power: 30 to 2,000 W, and preferably 50 to 700 W

Substrate temperature: not more than 500° C.

Reaction time: about 60 seconds (the time may be arbitrarily set)

Film thickness: 10 nm to 800 nm

In the film formation conditions, the substrate temperature is preferably within a range from 150° C. to 350° C., and more preferably within a range from 200° C. to 300° C. The substrate temperature is preferably about 200° C. (180° C. to 230° C.) in order to reduce the relative dielectric constant of the insulating film, and is preferably about 300° C. (250° C. to 320° C.) in order to enhance the mechanical strength. For this reason, the substrate temperature can be set at an appropriate temperature within this range in accordance with the intended physical properties.

In addition, in those cases where film formation is conducted without entraining an oxidizing gas, a heat treatment may be conducted on the insulating film by heating the substrate while a mixed gas of an inert gas and an oxidizing gas is caused to flow through the plasma film formation apparatus following the film formation. For example, nitrogen gas is used as the inert gas, and the substrate temperature is set, for example, within a range from 150° C. to 350° C., and preferably within a range from 200° C. to 300° C.

The insulating film formed by the plasma CVD method is subjected to a post treatment through ultraviolet (UV) irradiation, if necessary. Due to the ultraviolet irradiation, it is possible to remove the hydrocarbons present within the insulating film so as to reduce the relative dielectric constant. For example, the hydrocarbons to be removed include the hydrocarbons represented by a formula CxHy (where x=1 to 6, and y=3 to 11).

A known ultraviolet irradiation apparatus may be employed in the ultraviolet irradiation method, and for example, an ultraviolet irradiation apparatus such as that shown in FIG. 2 or the like is used.

The ultraviolet irradiation apparatus shown in FIG. 2 includes a chamber 21 that is able to be placed under reduced pressure, and this chamber 21 is connected to an exhaust pump 24 via an exhaust pipe 22 and an on-off valve 23. In addition, the chamber 21 is also equipped with a pressure gauge 25, which enables the pressure inside the chamber 21 to be measured. Further, a quartz plate 28 and a shutter 29 are provided inside the chamber 21 opposite to a mount 27 for mounting a substrate 26, and an ultraviolet lamp 30 is also provided on the back surface of the shutter 29.

Although not shown in the drawing, a heater is also provided inside the mount 27 for mounting the substrate 26, enabling the substrate 26 to be heated.

In addition, a gas supply pipe 31 is connected to the chamber 21, and an inert gas supply source that is not shown in the drawing is connected to this gas supply pipe 31, so that the inside of the chamber 21 can be maintained in an inert atmosphere. For example, nitrogen gas is used as the inert gas.

The substrate 26 is mounted on top of the mount 27 inside the chamber 21 of the ultraviolet irradiation apparatus, and ultraviolet irradiation is conducted by heating the substrate 26 with the heater provided in the mount 27 while causing an inert gas from, the inert gas supply source to flow inside the chamber 21. As a result, the insulating film on top of the substrate 26 is subjected to an ultraviolet irradiation treatment.

Preferred ranges for the ultraviolet irradiation conditions within this ultraviolet irradiation apparatus are indicated below, although the conditions are not necessarily restricted to these ranges.

Inert gas flow rate: 0 to 5 slm

Pressure: not more than 10 Torr

Substrate temperature: not more than 450° C., preferably from 350° C. to 450° C.

Ultraviolet intensity: about 430 mW/cm²

Ultraviolet wavelength: at least 200 nm, preferably from 350 to 400 nm

Ultraviolet irradiation time: 1 to 20 minutes

Distance between substrate and ultraviolet lamp: from 50 to 150 mm, preferably 108 mm

Among the ultraviolet irradiation conditions, the ultraviolet wavelength is a particularly important factor. It is necessary to conduct the ultraviolet irradiation treatment in the present invention without causing deterioration of the insulating film, and therefore, short-wavelength, high-energy ultraviolet rays cannot be employed. For this reason, ultraviolet rays having relatively low energy and a wavelength of at least 200 nm are employed, and the wavelength is preferably from 350 to 400 nm. The ultraviolet rays having a wavelength of less than 200 nm cause deterioration of the insulating film.

In addition, if the ultraviolet irradiation time is too short, the effects achieved by the ultraviolet irradiation do not fully spread within the insulating film, whereas if the ultraviolet irradiation time is too long, the treatment causes deterioration of the insulating film. Although the required irradiation time increases as the thickness of the insulating film increases, it is preferable not to exceed the maximum of 6 minutes.

Among other ultraviolet irradiation conditions, the substrate temperature adversely affects the thermal stability of the insulating film. A low substrate temperature leads to low thermal stability of the insulating film, which causes deterioration of the insulating film during the heating step of forming a multilayer wiring structure.

On the other hand, although a high substrate temperature enhances the thermal stability of the insulating film, since thermally weak portions within the multilayer wiring structure may deteriorate if the substrate temperature is too high, a substrate temperature of 350° C. to 450° C. is preferred.

Next, the insulating film of the present invention will be described.

The insulating film of the present invention is formed using the aforementioned insulating film material for plasma CVD, or a mixed gas of this material and an oxidizing gas, by conducting a plasma CVD reaction within a plasma film formation apparatus, and has a relative dielectric constant of about 2.4 to 2.6, as well as a superior plasma resistance.

The reasons that the insulating film obtained using the insulating film formation method according to the present invention exhibits a superior plasma resistance and also has a low relative dielectric constant are thought to be as follows.

The insulating film materials represented by the chemical formulas (1) to (5) are constituted of a silicon compound having a hydrocarbon group with a structure branched at the β carbon or γ carbon, or a hydrocarbon group with a ring structure. This silicon compound is capable of primarily generating a radical or ionic species represented by Si—(CH₂)ₓ upon exposure to the plasma atmosphere, which enables formation of a Si—(CH₂)ₓ—Si network within the insulating film on top of a wafer.

In other words, in the case of a structure in which an isobutyl group is directly bonded to silicon, because the bond energy of the isobutyl group between the α-position and the β-position is low, the bond is cleaved by a plasma to produce a SiC radical, thereby forming numerous Si—(CH₂)ₓ—Si networks within the insulating film.

Because the Si—(CH₂)ₓ—Si networks exhibit a high level of plasma resistance, optimal insulating films can be provided.

On the other hand, the insulating film materials represented by the chemical formulas (6) to (9) are constituted of a silicon compound having a n-propyl group. This silicon compound is capable of primarily generating a radical or ionic species represented by Si—(CH₂)ₓ upon exposure to the plasma atmosphere, which enables formation of an insulating film including a Si—(CH₂)ₓ—Si network on top of a wafer.

In other words, in the case of a structure in which a n-propyl group is directly bonded to silicon, the carbon-carbon bond of the n-propyl group is cleaved by a plasma to produce a SiC radical, thereby forming numerous Si—(CH₂)ₓ—Si networks within the insulating film.

Accordingly, as in the case of the insulating film materials represented by the chemical formulas (1) to (5), optimal insulating films can be provided.

Currently used SiCOH films include either a film structure that has a skeleton mainly formed from Si—O—Si as well as a hydrocarbon group introduced for reducing the dielectric constant, or a film structure in which a hydrocarbon and an analogous compound thereof are introduced within the film in advance as porogen and then the porogen is removed by a UV treatment to introduce vacancies.

In the present invention, not by simply introducing hydrocarbon groups into the film structure, but by employing many of the introduced hydrocarbon groups for the network represented by the formula Si—(CH₂)ₓ—Si, stable film structures can be achieved, and consequently, an insulating film exhibiting a particularly high level of plasma resistance can be obtained.

As an example for the formation of Si—(CH₂)ₓ—Si networks, an insulating film material constituted of a silicon compound that contains, among branched hydrocarbon groups, at least one hydrocarbon group having a structure so as to minimize the bond energy between the α carbon and the β carbon or between the β carbon and the γ carbon, may be deposited to form a film on top of a silicon wafer by a plasma CVD treatment so as to include numerous Si—(CH₂)ₓ—Si networks within the insulating film.

It is thought that for the reasons outlined above, the insulating film of the present invention has a low relative dielectric constant while providing a superior plasma resistance.

### EXAMPLES

A more detailed description of the present invention is presented below, based on a series of examples and comparative examples.

However, the scope of the present invention is in no way limited by the following examples.

### Example 1

### Formation of an Insulating Film without Using an Oxidizing Gas 1

A parallel plate-type capacitively coupled plasma CVD apparatus was used for forming the insulating film. An 8-inch (diameter: 200 mm) or 12-inch (diameter: 300 mm) silicon wafer was transported onto a susceptor that had been preheated to approximately 275° C., isobutyldimethylmethoxysilane (iBDMMOS) was caused to flow at a volume flow rate of 30 cc/minute as the insulating film material gas, and an insulating film was formed with the plasma-generating high-frequency power supply set to an output of 700 W. The pressure inside the chamber of the aforementioned plasma CVD apparatus at this time was 6 Torr.

An ultraviolet irradiation apparatus was used for reforming the insulating film formed through a plasma CVD reaction by the plasma film formation apparatus. The aforementioned silicon wafer having the insulating film formed thereon was transported onto a mount, nitrogen gas was caused to flow at a volume flow rate of 2 cc/minute, and the insulating film was reformed by setting the ultraviolet wavelength, ultraviolet intensity, distance between the wafer and an ultraviolet lamp and ultraviolet irradiation time, to about 310 nm, about 428 mW/cm², 108 mm and about 12 minutes, respectively. The pressure inside the chamber of the aforementioned ultraviolet irradiation apparatus at this time was 5 Torr, and the wafer temperature was 400° C.

In order to measure the relative dielectric constant of the obtained insulating film, the aforementioned silicon wafer was transported onto a CV measurement device 495 manufactured by Solid State Measurements, Inc., and a mercury electrode was used to measure the relative dielectric constant of the insulating film. The results of the measurement are shown in Table 1.

In order to evaluate the plasma resistance of the obtained insulating film, a method was employed in which the parallel plate-type capacitively coupled plasma CVD apparatus was used once again. A plasma was generated in a NH₃ atmosphere (NH₃ plasma), and the NH₃ plasma was irradiated. The plasma application time was 10 seconds and 120 seconds.

Subsequently, the relative dielectric constant of this insulating film subjected to the NH₃ plasma treatment was measured on the aforementioned CV measurement device 495 manufactured by Solid State Measurements, Inc. The results of the measurement are shown in Table 1.

### Example 2

### Formation of an Insulating Film without Using an Oxidizing Gas 2

A parallel plate-type capacitively coupled plasma CVD apparatus was used for forming the insulating film. An 8-inch (diameter: 200 mm) or 12-inch (diameter: 300 mm) silicon wafer was transported onto a susceptor that had been preheated to approximately 275° C., 5-silaspiro-[4,4]-nonane (SSN) was caused to flow at a volume flow rate of 30 cc/minute as the insulating film material gas, and an insulating film was formed with the plasma-generating high-frequency power supply set to an output of 150 W. The pressure inside the chamber of the aforementioned, plasma CVD apparatus at this time was 4 Torr.

In order to evaluate the plasma resistance of the obtained insulating film, a method was employed in which the parallel plate-type capacitively coupled plasma CVD apparatus was used once again. A plasma was generated in a NH₃ atmosphere (NH₃ plasma), and the NH₃ plasma was irradiated. The plasma application time was 10 seconds.

Subsequently, the relative dielectric constant of this insulating film subjected to the NH3 plasma treatment was measured on the aforementioned CV measurement device 495 manufactured by Solid State Measurements, Inc. The results of the measurement are shown in Table 1.

### Example 3

### Formation of an Insulating Film without Using an Oxidizing Gas 3

The apparatus and method used for forming the insulating film were substantially the same as those employed in Example 1, although diisobutyldimethylsilane (DiBDMS) was caused to flow at a volume flow rate of 30 cc/minute as the insulating film material gas, and an insulating film was formed with the plasma-generating high-frequency power supply set to an output of 700 W. The pressure inside the chamber of the aforementioned plasma CVD apparatus at this time was 6 Torr.

In addition, the apparatus and method used for subjecting the insulating film following deposition to an ultraviolet irradiation treatment are the same as those employed in Example 1.

The relative dielectric constant and the plasma resistance of the obtained insulating film were evaluated in the same manner as in Example 1. The results of the measurements for the relative dielectric constant and plasma resistance are shown in Table 1.

### Example 4

### Formation of an Insulating Film without Using an Oxidizing Gas 4

The apparatus and method used for forming the insulating film were substantially the same as those employed in Example 1, although diisobutylethylsilane (DiBES) was caused to flow at a volume flow rate of 30 cc/minute as the insulating film material gas, and an insulating film was formed with the plasma-generating high-frequency power supply set to an output of 550 W. The pressure inside the chamber of the aforementioned plasma CVD apparatus at this time was 6 Torr.

In addition, the apparatus and method used for subjecting the insulating film following deposition to an ultraviolet irradiation treatment are the same as those employed in Example 1.

The relative dielectric constant and the plasma resistance of the obtained insulating film were evaluated in the same manner as in Example 1. The results of the measurements for the relative dielectric constant and plasma resistance are shown in Table 1.

### Example 5

### Formation of an Insulating Film with Concomitant Use of an Oxidizing Gas

The apparatus and method used for forming the insulating film were substantially the same as those employed in Example 1, although isobutyltrimethylsilane (iBTMS) was caused to flow at a volume flow rate of 30 cc/minute as the insulating film material gas, oxygen was caused to flow at a volume flow rate of 10 cc/minute as the oxidizing gas, and an insulating film was formed with the plasma-generating high-frequency power supply set to an output of 550 W. The pressure inside the chamber of the aforementioned plasma CVD apparatus at this time was 6 Torr.

In addition, the apparatus and method used for subjecting the insulating film following deposition to an ultraviolet irradiation treatment are the same as those employed in Example 1.

The relative dielectric constant and the plasma resistance of the obtained insulating film were evaluated in the same manner as in Example 1. The results of the measurements for the relative dielectric constant and plasma resistance are shown in Table 1.

### Example 6

### Formation of an Insulating Film with Concomitant Use of an Oxidizing Gas 2

The apparatus and method used for forming the insulating film were substantially the same as those employed in Example 1, although diisobutyldimethylsilane (DiBDMS) was caused to flow at a volume flow rate of 30 cc/minute as the insulating film material gas, oxygen was caused to flow at a volume flow rate of 12 cc/minute as the oxidizing gas, and an insulating film was formed with the plasma-generating high-frequency power supply set to an output of 650 W. The pressure inside the chamber of the aforementioned plasma CVD apparatus at this time was 6 Torr.

In addition, the apparatus and method used for subjecting the insulating film following deposition to an ultraviolet irradiation treatment are the same as those employed in Example 1.

The relative dielectric constant and the plasma resistance of the obtained insulating film were evaluated in the same manner as in Example 1. The results of the measurements for the relative dielectric constant and plasma resistance are shown in Table 1.

### Comparative Example 1

The relative dielectric constant and the plasma resistance of the insulating film obtained from an insulating film Aurora 2.5 which has been commercially available and generally used were evaluated in the same manner as in Example 1. The results of the measurements for the relative dielectric constant and plasma resistance are shown in Table 1.

In this example, no oxidizing gas was entrained.

TABLE 1

| | | 10 seconds of | 120 seconds of |
|---|---|---|---|
| | Before irradiation | irradiation | irradiation |
| Ex. 1 | 2.60 | 2.74 | 2.86 |
| Ex. 2 | 2.65 | 2.68 | — |
| Ex. 3 | 2.80 | 2.89 | 3.02 |
| Ex. 4 | 2.89 | 2.99 | 3.13 |
| Ex. 5 | 2.86 | 2.94 | 3.09 |
| Ex. 6 | 2.76 | 2.87 | 3.01 |
| Comp. Ex. 1 | 2.62 | 2.82 | 3.27 |

From the results shown in Table 1, it became apparent that the insulating film obtained in Example 1 exhibited a relative dielectric constant of 2.60 before UV irradiation, a relative dielectric constant of 2.74 (an increase rate of 5.38%) when the NH₃ plasma was induced for 10 seconds, and a relative dielectric constant of 2.86 (an increase rate of 10%) when the NH₃ plasma was induced for 120 seconds.

From the results shown in Table 1, it became apparent that the insulating film obtained in Example 2 exhibited a relative dielectric constant of 2.65 before UV irradiation and a relative dielectric constant of 2.68 (an increase rate of 1.13%) when the NH₃ plasma was induced for 10 seconds.

From the results shown in Table 1, it became apparent that the insulating film obtained in Example 3 exhibited a relative dielectric constant of 2.80 before UV irradiation, a relative dielectric constant of 2.89 (an increase rate of 3.21%) when the NH₃ plasma was induced for 10 seconds, and a relative dielectric constant of 3.02 (an increase rate of 7.86%) when the NH₃ plasma was induced for 120 seconds.

From the results shown in Table 1, it became apparent that the insulating film obtained in Example 4 exhibited a relative dielectric constant of 2.89 before UV irradiation, a relative dielectric constant of 2.99 (an increase rate of 3.46%) when the NH₃ plasma was induced for 10 seconds, and a relative dielectric constant of 3.13 (an increase rate of 8.30%) when the NH₃ plasma was induced for 120 seconds.

From the results shown in Table 1, it became apparent that the insulating film obtained in Example 5 exhibited a relative dielectric constant of 2.86 before UV irradiation, a relative dielectric constant of 2.94 (an increase rate of 2.80%) when the NH₃ plasma was induced for 10 seconds, and a relative dielectric constant of 3.09 (an increase rate of 8.04%) when the NH₃ plasma was induced for 120 seconds.

From the results shown in Table 1, it became apparent that the insulating film obtained in Example 6 exhibited a relative dielectric constant of 2.76 before UV irradiation, a relative dielectric constant of 2.87 (an increase rate of 3.98%) when the NH₃ plasma was induced for 10 seconds, and a relative dielectric constant of 3.01 (an increase rate of 9.06%) when the NH₃ plasma was induced for 120 seconds.

From the results shown in Table 1, it became apparent that the insulating film obtained in Comparative Example 1 exhibited a relative dielectric constant of 2.62 before UV irradiation, a relative dielectric constant of 2.82 (an increase rate of 7.63%) when the NH₃ plasma was induced for 10 seconds, and a relative dielectric constant of 3.27 (an increase rate of 24.8%) when the NH₃ plasma was induced for 120 seconds.

It should be noted that although it is not practical to irradiate a NH₃ plasma for 120 seconds as a process during the formation of a large-scale integration (LSI) wiring, it can be said, according to the present invention, that the plasma resistance was high due to the low increase rate for the relative dielectric constant even if the irradiation time was long.

As described above, by forming an insulating film using the insulating film materials constituted of the silicon compounds represented by the aforementioned chemical formulas (1) to (5) through the plasma CVD method at an adequate film forming temperature, followed by reforming of this insulating film through an adequate ultraviolet irradiation treatment, an insulating film exhibiting a high plasma resistance as well as a low relative dielectric constant can be formed.

### Example 7

By using a parallel plate-type capacitively coupled plasma CVD apparatus, an 8-inch silicon wafer was transported onto a susceptor that had been preheated to approximately 275° C., a film forming material indicated in Table 2 (i.e., an insulating film material gas) was caused to flow at a volume flow rate of 30 cc/minute, and an insulating film was formed with the plasma-generating high-frequency power supply set to an output of 700 W.

Further, in those cases where an oxidizing gas was used, oxygen (O₂) was used as the oxidizing gas at a flow rate of 10 cc/minute. The pressure inside the chamber of the aforementioned plasma CVD apparatus at this time was 6 Torr.

The film forming time was set arbitrarily while the film thickness following deposition was set to a constant of 300 nm.

An ultraviolet irradiation apparatus was used for reforming the insulating film formed through a plasma CVD reaction by the plasma film formation apparatus. The aforementioned silicon wafer having the insulating film formed thereon was transported onto a mount, nitrogen gas was caused to flow at a volume flow rate of 2 cc/minute, and the insulating film was reformed by setting the ultraviolet wavelength, ultraviolet intensity, distance between the wafer and an ultraviolet lamp, and ultraviolet irradiation time, to about 310 nm, about 428 mW/cm², 108 mm and about 12 minutes, respectively. The pressure inside the chamber of the aforementioned ultraviolet irradiation apparatus at this time was 5 Torr, and the wafer temperature was 400° C.

The dielectric constant and the infrared absorption spectrum of this insulating film formed on the silicon wafer were measured using the CV measurement device 495 manufactured by Solid State Measurements, Inc., and an FTIR device manufactured by JASCO Corporation, respectively.

The results are shown in Table 2.

TABLE 2

| | Oxidizing | Dielectric | Si—CH₂—Si absorption |
|---|---|---|---|
| Film forming material | agent (O₂) | constant | peak area |
| Isobutyldimethylmethoxysilane | Absent | 2.6 | 0.030 |
| Diisobutyldimethoxysilane | Absent | 2.6 | 0.032 |
| Isobutylditrimethylsilane | Present | 2.5 | 0.031 |
| Diisobutyldimethylsilane | Absent | 2.8 | 0.034 |
| Diisobutylethylsilane | Absent | 2.8 | 0.035 |
| Diisobutyldimethylsilane | Present | 2.6 | 0.030 |
| 1-1-diisobutyl-1- | Present | 2.6 | 0.045 |
| silacyclopentane | | | |
| Propyltrimethylsilane | Present | 2.5 | 0.028 |
| Dipropyldimethylsilane | Present | 2.6 | 0.023 |
| 1-1-divinyl-1-silacyclopentane | Present | 2.5 | 0.061 |
| 5-silaspiro[4,4]nonane | Present | 2.5 | 0.063 |
| Aurora 2.5 (Comparative Example) | — | 2.5 | 0.000 |

From the results shown in Table 2, the presence of an infrared absorption peak due to Si—(CH₂)—Si was verified within the insulating film formed using the film forming material indicated in Example 4. In other words, since these insulating films contained numerous Si—(CH₂)ₓ—Si networks exhibiting a high level of plasma resistance, it was confirmed that the film forming material indicated in Example 4 was capable of forming a film with a high plasma resistance.

### Example 8

### Formation of an Insulating Film without Using an Oxidizing Gas 3

A parallel plate-type capacitively coupled plasma CVD apparatus was used for forming the insulating film. An 8-inch (diameter: 200 mm) silicon wafer was transported onto a susceptor that had been preheated to approximately 220° C., tripropylmethoxysilane (TPMOS) was caused to flow at a volume flow rate of 41.5 cc/minute as the insulating film material gas, and an insulating film was formed with the plasma-generating high-frequency power supply set to an output of 300 W. The pressure inside the chamber of the aforementioned plasma CVD apparatus at this time was 13 Torr.

An ultraviolet irradiation apparatus was used for reforming the insulating film formed through a plasma CVD reaction by the plasma film formation apparatus. The aforementioned silicon wafer having the insulating film formed thereon was transported onto a mount preheated to about 400° C., nitrogen gas was caused to flow at a volume flow rate of 2 L/minute, and the insulating film was reformed by setting the ultraviolet wavelength, ultraviolet intensity, distance between the wafer and an ultraviolet lamp, and ultraviolet irradiation time, to about 310 nm, about 428 mW/cm², 108 mm and about 4 minutes, respectively. The pressure inside the chamber of the aforementioned ultraviolet irradiation apparatus at this time was 5 Torr.

In order to measure the relative dielectric constant of the obtained insulating film, the aforementioned silicon wafer was transported onto a CV measurement device 495 manufactured by Solid State Measurements, Inc., and a mercury electrode was used to measure the relative dielectric constant of the insulating film. As a result, the relative dielectric constant of the insulating film was 2.24.

In order to evaluate the plasma resistance of the obtained insulating film, a method was employed in which the parallel plate-type capacitively coupled plasma CVD apparatus was used once again. A plasma was generated in a NH₃ atmosphere (NH₃ plasma), and the NH₃ plasma was irradiated to this insulating film. The irradiation time may be generally set to about 10 to about 120 seconds. In the present example, the plasma was irradiated for 60 seconds.

Subsequently, the relative dielectric constant of this insulating film subjected to the NH₃ plasma treatment was measured on the aforementioned CV measurement device 495 manufactured by Solid State Measurements, Inc.

Furthermore, the abundance of Si—CH₂—Si bonds (in the form of a Si—CH₂—Si absorption peak area) within the insulating film was measured. In the present invention, not by simply introducing hydrocarbon groups into the film structure, but by employing many of the introduced hydrocarbon groups for forming the network represented by the formula Si—(CH₂)ₓ—Si, stable film structures can be achieved, and consequently, an insulating film exhibiting a particularly high level of plasma resistance can be obtained. Accordingly, the evaluation was conducted based on the Si—CH₂—Si absorption peak area and not on the atomic weight of carbon.

Small Si—CH₂—Si absorption peak areas indicate a low plasma resistance since the Si—CH₂—Si bonds are either absent or low in abundance, whereas large Si—CH₂—Si absorption peak areas indicate a high plasma resistance since the abundance of Si—CH₂—Si bonds is high.

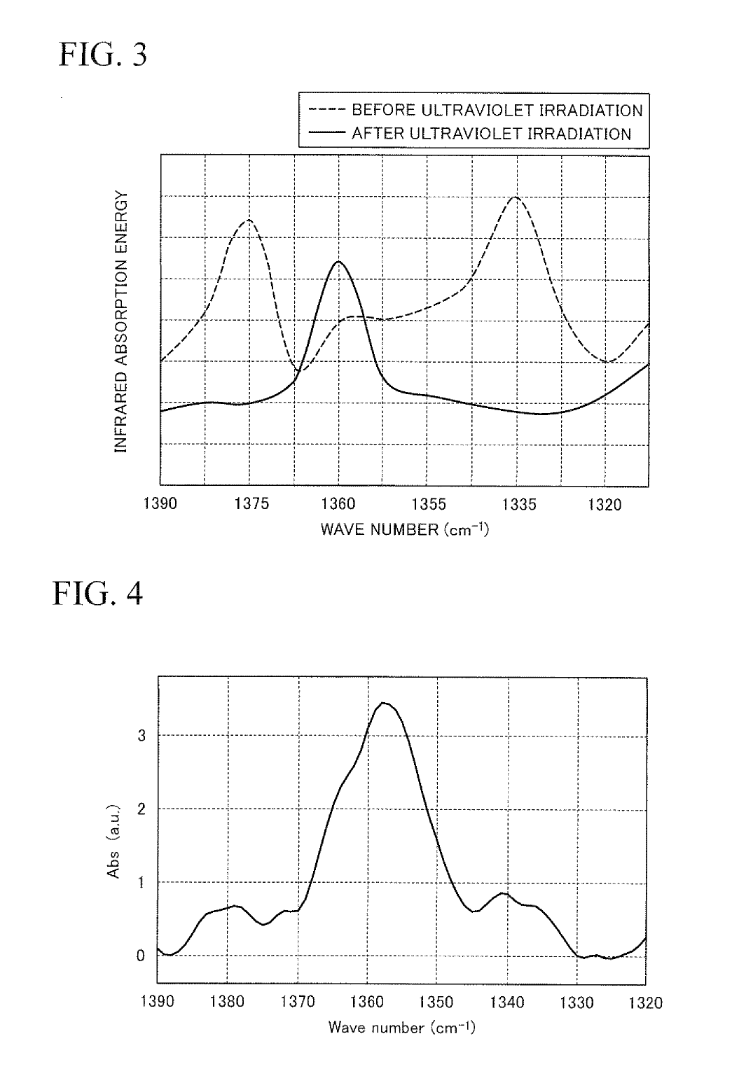

FIG. 3 shows an example of an infrared absorption spectrum of an insulating film, and illustrates an infrared absorption spectrum of the insulating film before ultraviolet irradiation and an infrared absorption spectrum of the insulating film after ultraviolet irradiation. Peaks of the infrared absorption spectrum for the insulating film before ultraviolet irradiation appear at wave numbers of 1,335 cm⁻³ and 1,375 cm⁻¹, each of which indicates the abundance of a precursor of Si—CH₂—Si bonds.

On the other hand, a peak of the infrared absorption spectrum after ultraviolet irradiation appears at a wave number of 1,360 cm⁻¹, which indicates the abundance of Si—CH₂—Si bonds.

As described above, since the infrared absorption spectrum changes before and after the ultraviolet irradiation treatment, precursors of Si—CH₂—Si bonds within the insulating film change into Si—CH₂—Si bonds, and the plasma resistance of the insulating film can be evaluated from the abundance of Si—CH₂—Si bonds within the insulating film following the ultraviolet irradiation treatment.

The infrared absorption spectrum of the aforementioned silicon wafer was measured using the infrared spectrophotometer Spectrum 400 manufactured by PerkinElmer Inc., in order to measure the Si—CH₂—Si bonds within the obtained insulating film. This infrared absorption spectrum is shown in FIG. 4.

The relative dielectric constant of the insulating film after ultraviolet irradiation, the relative dielectric constant of the insulating film subjected to a NH₃ plasma treatment, and the Si—CH₂—Si absorption peak area are indicated in Table 4.

In addition, the atomic weight of carbon for the obtained insulating film was measured by X-ray photoelectron spectroscopy (XPS). As a result, inclusion of 53.2% of carbon was confirmed. The results are shown in Table 4.

### Example 9

### Formation of an Insulating Film without Using an Oxidizing Gas 4

A parallel plate-type capacitively coupled plasma CVD apparatus was used for forming the insulating film. A 12-inch (diameter: 300 mm) silicon wafer was transported onto a susceptor that had been preheated to approximately 200° C., tripropylmethoxysilane (TnPMOS) was caused to flow at a volume flow rate of 52.5 cc/minute as the insulating film material gas, and an insulating film was formed with the plasma-generating high-frequency power supply set to an output of 800 W. The pressure inside the chamber of the aforementioned plasma CVD apparatus at this time was 11 Torr.

An ultraviolet irradiation apparatus was used for reforming the insulating film formed through a plasma CVD reaction by the plasma film formation apparatus. The aforementioned silicon wafer having the insulating film formed thereon was transported onto a mount preheated to about 400° C., nitrogen gas was caused to flow at a volume flow rate of 2 L/minute, and the insulating film was reformed by setting the ultraviolet wavelength, ultraviolet intensity, distance between the wafer and an ultraviolet lamp, and ultraviolet irradiation time, to about 310 nm, about 428 mW/cm², 108 mm and about 6 minutes, respectively. The pressure inside the chamber of the aforementioned ultraviolet irradiation apparatus at this time was 5 Torr.

The relative dielectric constant of the insulating film after ultraviolet irradiation, the relative dielectric constant of the insulating film subjected to a NH₃ plasma treatment, and the Si—CH₂—Si absorption peak area were evaluated in the same manner as in Example 8. The evaluation results are shown in Table 3. The infrared absorption spectrum is shown in FIG. 5.

### Example 10

### Formation of an Insulating Film without Using an Oxidizing Gas 5

A parallel plate-type capacitively coupled plasma CVD apparatus was used for forming the insulating film. An 8-inch (diameter: 200 mm) silicon wafer was transported onto a susceptor that had been preheated to approximately 200° C., tri-n-propylmethoxysilane (TOMOS) was caused to flow at a volume flow rate of 41.5 cc/minute as the insulating film material gas, and an insulating film was formed with the plasma-generating high-frequency power supply set to an output of 300 W. The pressure inside the chamber of the aforementioned plasma CVD apparatus at this time was 13 Torr.

An ultraviolet irradiation apparatus was used for reforming the insulating film formed through a plasma CVD reaction by the plasma film formation apparatus. The aforementioned silicon wafer having the insulating film formed thereon was transported onto a mount preheated to about 400° C., nitrogen gas was caused to flow at a volume flow rate of 2 L/minute, and the insulating film was reformed by setting the ultraviolet wavelength, ultraviolet intensity, distance between the wafer and an ultraviolet lamp, and ultraviolet irradiation time, to about 310 nm, about 428 mW/cm², 108 mm and about 10 minutes, respectively. The pressure inside the chamber of the aforementioned ultraviolet irradiation apparatus at this time was 5 Torr.

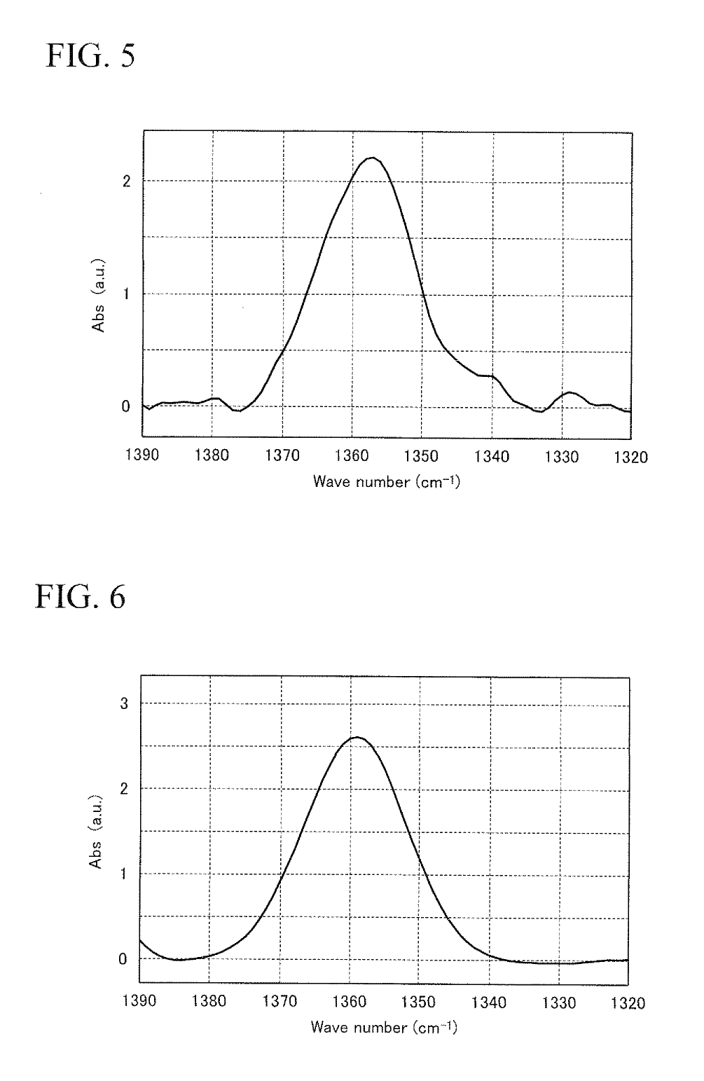

The relative dielectric constant of the insulating film after ultraviolet irradiation, the relative dielectric constant of the insulating film subjected to a NH₃ plasma treatment, and the Si—CH₂—Si absorption peak area were evaluated in the same manner as in Example 8. The evaluation results are shown in Table 3. The infrared absorption spectrum is shown in FIG. 6.

### Comparative Example 2

The relative dielectric constant and the plasma resistance of the insulating film obtained from an insulating material dimethyldimethoxysilane (DMDMOS) which has been commercially available and generally used were evaluated in the same manner as in Example 10. It should be noted that in this example, no oxidizing gas was entrained during film formation.

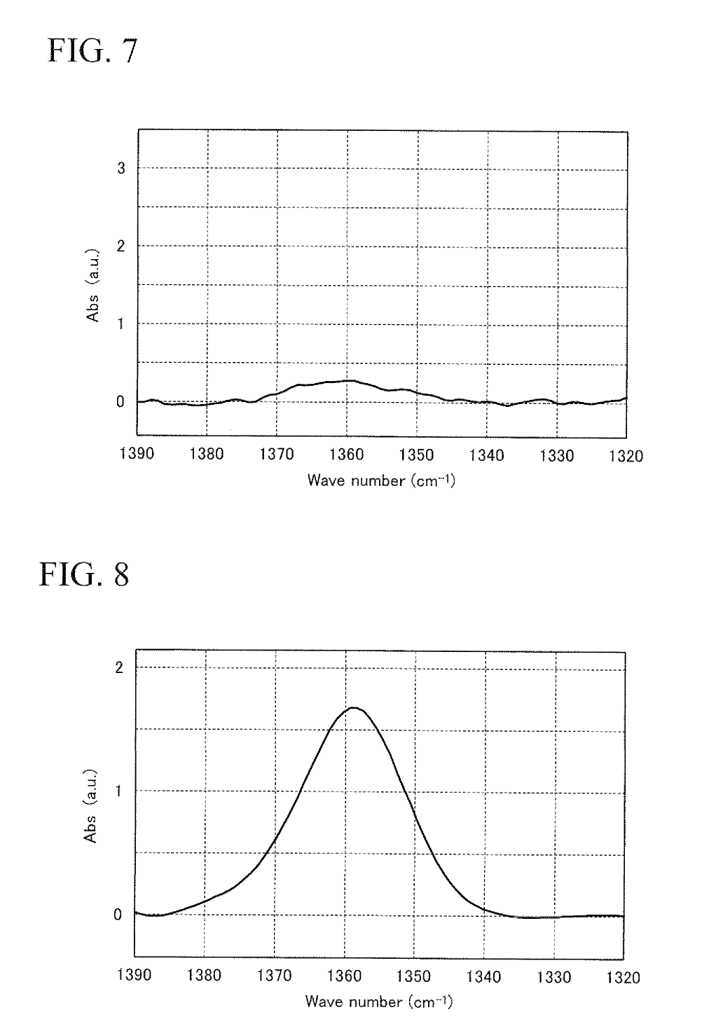

The relative dielectric constant of the insulating film after ultraviolet irradiation, the relative dielectric constant of the insulating film subjected to a NH₃ plasma treatment, and the Si—CH₂—Si absorption peak area were evaluated in the same manner as in Example 8. The evaluation results are shown in Table 1. The infrared absorption spectrum is shown in FIG. 7.

### Comparative Example 3

### Formation of an Insulating Film by High Temperature Film Formation

A parallel plate-type capacitively coupled plasma CVD apparatus was used for forming the insulating film. An 8-inch (diameter: 200 mm) silicon wafer was transported onto a susceptor that had been preheated to approximately 275° C., tripropylmethoxysilane (TPMOS) was caused to flow at a volume flow rate of 41.5 cc/minute as the insulating film material gas, and an insulating film was formed with the plasma-generating high-frequency power supply set to an output of 300 W. The pressure inside the chamber of the aforementioned plasma CVD apparatus at this time was 13 Torr.

An ultraviolet irradiation apparatus was used for reforming the insulating film formed through a plasma CVD reaction by the plasma film formation apparatus. The aforementioned silicon wafer having the insulating film formed thereon was transported onto a mount preheated to about 400° C., nitrogen gas was caused to flow at a volume flow rate of 2 L/minute, and the insulating film was reformed by setting the ultraviolet wavelength, ultraviolet intensity, distance between the wafer and an ultraviolet lamp, and ultraviolet irradiation time, to about 310 nm, about 428 mW/cm², 108 mm and about 10 minutes, respectively. The pressure inside the chamber of the aforementioned ultraviolet irradiation apparatus at this time was 5 Torr.

The relative dielectric constant of the insulating film after ultraviolet irradiation, the relative dielectric constant of the insulating film subjected to a NH₃ plasma treatment, and the Si—CH₂—Si absorption peak area were evaluated in the same manner as in Example 8. The evaluation results are shown in Table 3. The infrared absorption spectrum is shown in FIG. 8.

TABLE 3

| | Relative dielectric constant | | | |
|---|---|---|---|---|
| | | After NH₃ | Si—CH₂—Si absorption peak area | |
| | After UV | plasma | Before UV | After UV |
| | irradiation | irradiation | irradiation | irradiation |
| Ex. 8 | 2.24 | 2.45 | 0.01 | 0.06 |
| Ex. 9 | 2.21 | 2.42 | 0.01 | 0.062 |
| Ex. 10 | 2.41 | 2.65 | 0.011 | 0.068 |
| Comp. | 2.6 | 2.93 | 0 | 0.003 |
| Ex. 2 | | | | |
| Comp. | 2.55 | 2.82 | 0.005 | 0.042 |
| Ex. 3 | | | | |

TABLE 4

| | C | O | Si |
|---|---|---|---|
| Elemental | 53.2 | 25 | 21.8 |
| composition | | | |
| (atomic %) | | | |

From the results shown in Table 3, it became apparent that the insulating film obtained in Example 5 exhibited a relative dielectric constant of 2.24 after ultraviolet irradiation, and a relative dielectric constant of 2.45 (an increase rate of 9%) when the NH₃ plasma was induced for 60 seconds. In addition, it became clear that the Si—CH₂—Si absorption peak area before ultraviolet irradiation was 0.010, and the Si—CH₂—Si absorption peak area after ultraviolet irradiation was 0.060.

From the results shown in Table 3, it became apparent that the insulating film obtained in Example 6 exhibited a relative dielectric constant of 2.21 after ultraviolet irradiation, and a relative dielectric constant of 2.42 (an increase rate of 10%) when the NH₃ plasma was induced for 60 seconds. In addition, it became clear that the Si—CH₂—Si absorption peak area before ultraviolet irradiation was 0.010, and the Si—CH₂—Si absorption peak area after ultraviolet irradiation was 0.062.

From the results shown in Table 3, it became apparent that the insulating film obtained in Example 7 exhibited a relative dielectric constant of 2.41 after ultraviolet irradiation, and a relative dielectric constant of 2.65 (an increase rate of 10%) when the NH₃ plasma was induced for 60 seconds. In addition, it became clear that the Si—CH₂—Si absorption peak area before ultraviolet irradiation was 0.011, and the Si—CH₂—Si absorption peak area after ultraviolet irradiation was 0.068.

From the results shown above, it became clear that by forming an insulating film using the insulating film materials for plasma CVD constituted of the silicon compounds represented by the aforementioned chemical formulas (6) to (9) through the plasma CVD method at an adequate film forming temperature, followed by reforming of this insulating film through an adequate ultraviolet irradiation treatment, an insulating film exhibiting a high plasma resistance as well as a low relative dielectric constant can be formed.

From the results shown in Table 3, it became apparent that the insulating film obtained in Comparative Example 2 exhibited a relative dielectric constant of 2.60 after ultraviolet irradiation, and a relative dielectric constant of 2.93 (an increase rate of 13%) when the NH₃ plasma was induced for 60 seconds. In addition, it became clear that the Si—CH₂—Si absorption peak area before ultraviolet irradiation was 0.000, and the Si—CH₂—Si absorption peak area after ultraviolet irradiation was 0.003.

From the results obtained in Comparative Example 2, it became clear that even if an insulating film is formed using DMDMOS which is a conventional insulating film forming material through the plasma CVD method, followed by ultraviolet irradiation, this insulating film cannot be reformed.

From the results shown in Table 3, it became apparent that the insulating film obtained in Comparative Example 3 exhibited a relative dielectric constant of 2.55 after ultraviolet irradiation, and a relative dielectric constant of 2.82 (an increase rate of 11%) when the NH₃ plasma was induced for 60 seconds. In addition, it became clear that the Si—CH₂—Si absorption peak area before ultraviolet irradiation was 0.005, and the Si—CH₂—Si absorption peak area after ultraviolet irradiation was 0.042.

From the results obtained in Comparative Example 3, it became clear that if the film forming temperature is relatively high as 275° C., only insulating films exhibiting a relative dielectric constant substantially equivalent to that of the insulating film formed using DMDMOS which is a conventional insulating film forming material can be formed, although they exhibit a high level of plasma resistance.

### INDUSTRIAL APPLICABILITY

The present invention can be applied to semiconductor devices that use the type of highly integrated LSI wiring required in next generation applications.

### REFERENCE SIGNS LIST

1: Chamber
2: Exhaust pipe
3: On-off valve
4: Exhaust pump
5: Upper electrode
6: Lower electrode
7: High-frequency power source
8: Substrate
9: Heater
10: Gas supply pipe
21: Chamber
22: Exhaust pipe
23: On-off valve
24: Exhaust pump
25: Pressure gauge
26: Substrate (wafer)
27: Mount (susceptor)
28: Quartz plate
29: Shutter
30: Ultraviolet lamp
31: Gas supply pipe

1. An insulating film material for plasma CVD comprising: a silicon compound that includes two hydrocarbon groups bonded to each other to form a ring structure together with a silicon atom, or at least one branched hydrocarbon group,
wherein within the branched hydrocarbon group, α-carbon that is a carbon atom bonded to the silicon atom constitutes a methylene group, and β-carbon that is a carbon atom bonded to the methylene group or γ-carbon that is a carbon atom bonded to the β-carbon is a branching point.

2. The insulating film material for plasma CVD according to claim 1, wherein the branched hydrocarbon group is an i-butyl group, an i-pentyl group, a neopentyl group or a neohexyl group.

3. The insulating film material for plasma CVD according to claim 2, wherein the silicon compound is a compound represented by a chemical formula (1) shown below, which includes an i-butyl group, an i-pentyl group, a neopentyl group or a neohexyl group, and also includes an oxygen atom: 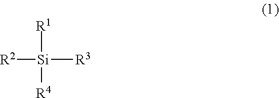
wherein each of R¹ to R⁴ represents any one of moieties selected from the group consisting of H, CₙH₂ₙ₊₁, CₖH₂ₖ₋₁, CₗH₂ₗ₋₃, OCₙH₂ₙ₊₁, OCₖH₂ₖ₋₁ and OC₁H₂ₗ₋₃, n represents an integer of 1 to 5, and k and l represent an integer of 2 to 6; with the proviso that any two of R¹ to R⁴ represents any one of moieties selected from the group consisting of CH₂CH(CH₃)CH₃, CH₂CH(CH₃)CH₂CH₃, CH₂CH₂CH(CH₃)CH₃, CH₂C(CH₃)₂CH₃ and CH₂CH₂C(CH₃)₂CH₃, and any one of OCH₃ and OC₂H₅.

4. The insulating film material for plasma CVD according to claim 2, wherein the silicon compound is a compound represented by a chemical formula (2) or a chemical formula (3) shown below, which includes an i-butyl group, an i-pentyl group, a neopentyl group or a neohexyl group, and includes no oxygen atom: 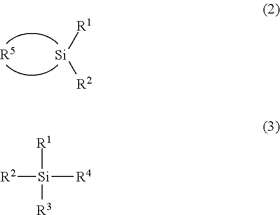
wherein each of R¹ to R⁴ represents any one of moieties selected from the group consisting of H, CₙH₂ₙ₊₁, CₖH₂ₖ₋₁ and CₗH₂ₗ₋₃, R⁵ represents CₓH₂ₓ, n represents an integer of 1 to 5, k and l represent an integer of 2 to 6, and x represents an integer of 3 to 7; with the proviso that any one of R¹ to R⁴ represents any one of moieties selected from the group consisting of CH₂CH(CH₃)CH₃, CH₂CH(CH₃)CH₂CH₃, CH₂CH₂CH(CH₃)CH₃, CH₂C(CH₃)₂CH₃ and CH₂CH₂C(CH₃)₂CH₃.

5. The insulating film material for plasma CVD according to claim 1, wherein the silicon compound is a compound represented by a chemical formula (4) or a chemical formula (5) shown below, which includes no oxygen atom: 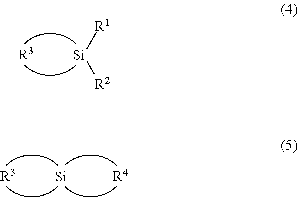
wherein each of R¹ to R² represents any one of moieties selected from the group consisting of H, CₙH₂ₙ₊₁, CₖH₂ₖ₋₁ and CₗH₂ₗ₋₃, R³ to R⁴ represent CₓH₂ₓ, n represents an integer of 1 to 5, k and l represent an integer of 2 to 6, and x represents an integer of 3 to 7.

6. An insulating film material for plasma CVD comprising a silicon compound that includes an i-butyl group or a n-propyl group.

7. The insulating film material for plasma CVD according to claim 6, wherein the silicon compound is a compound represented by a chemical formula (6) shown below, which includes an i-butyl group or a n-propyl group, and also includes an oxygen atom: 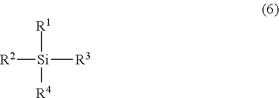
wherein each of R¹ to R⁴ represents any one of moieties selected from the group consisting of H, CₙH₂ₙ₊₁, CₖH₂ₖ₋₁, CₗH₂ₗ₋₃, OCₙH₂ₙ₊₁, OCₖH₂ₖ₋₁ and OCₗH₂ₗ₋₃, n represents an integer of 1 to 5, and k and l represent an integer of 2 to 6; with the proviso that any three of R¹ to R⁴ represents any one of moieties selected from the group consisting of H, CH₃, CH₂CH₃, CH₂CH₂CH₃, CH₂CH(CH₃)CH₃, CH₂CH(CH₃)C₂H₅, CH₂CH₂CH(CH₃)CH₃, CH₂C(CH₃)₂CH₃ and CH₂CH₂C(CH₃)₂CH₃, any one of OCH₃ and OC₂H₅, and any one of an i-butyl group and a n-propyl group.

8. The insulating film material for plasma CVD according to claim 6, wherein the silicon compound is a compound represented by a chemical formula (7) shown below, which includes an i-butyl group or a n-propyl group, and includes no oxygen atom: 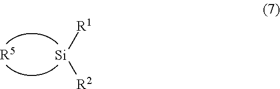
wherein each of R¹, R² and R⁵ represents any one of moieties selected from the group consisting of H, CₘH₂ₘ, CₙH₂ₙ₊₁, CₖH₂ₖ₋₁ and CₗH₂ₗ₋₃, n and m represent an integer of 1 to 5, and k and l represent an integer of 2 to 6; with the proviso that R¹ and R² represents any one of moieties selected from the group consisting of H, CH₃, CH₂CH₃, CH₂CH₂CH₃, CH₂CH(CH₃)CH₃, CH₂CH(CH₃)C₂H₅, CH₂CH₂CH(CH₃)CH₃, CH₂C(CH₃)₂CH₃ and CH₂CH₂C(CH₃)₂CH₃, and any one of an i-butyl group and a n-propyl group, and R⁵ represents any one of (CH₂)₃, (CH₂)₄ and (CH₂)₅.

9. The insulating film material for plasma CVD according to claim 6, wherein the silicon compound is a compound represented by a chemical formula (8) shown below, which includes an i-butyl group or a n-propyl group, and includes no oxygen atom: 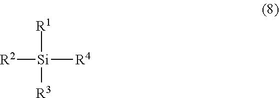
wherein each of R¹ to R⁴ represents any one of moieties selected from the group consisting of H, CₙH₂ₙ, CₙH₂ₙ₊₁, CₖH₂ₖ₋₁ and CₗH₂ₗ₋₃, n represents an integer of 1 to 5, and k and l represent an integer of 2 to 6; with the proviso that any two of R¹ to R⁴ represents any one of moieties selected from the group consisting of H, CH₃, CH₂CH₃, CH₂CH₂CH₃, CH₂CH(CH₃)CH₃, CH₂CH(CH₃)C₂H₅, CH₂CH₂CH(CH₃)CH₃, CH₂C(CH₃)₂CH₃ and CH₂CH₂C(CH₃)₂CH₃, and any one of an i-butyl group and a n-propyl group.

10. The insulating film material for plasma CVD according to claim 1, wherein the silicon compound is a compound represented by a chemical formula (9) shown below, which includes an i-butyl group or a n-propyl group, and also includes an oxygen atom: 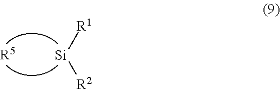
wherein R¹ and R² represent any one of OCH₃ and OC₂H₅, and any one of an i-butyl group and a n-propyl group, and R⁵ represents any one of (CH₂)₃, (CH₂)₄ and (CH₂)₅.

11. The insulating film material for plasma CVD according to claim 1 which has a boiling point at 1 atmospheric pressure of 300° C. or less.

12. A film formation method comprising: forming an insulating film by a plasma CVD method using the insulating film material for plasma CVD according to claim 1 or a mixed gas of this insulating film material for plasma CVD and an oxidizing gas.

13. The film formation method according to claim 12, further comprising subjecting the insulating film to ultraviolet irradiation.

14. The film formation method according to claim 12, wherein the oxidizing gas is an oxygen-containing compound.

15. The film formation method according to claim 12, wherein a film forming temperature is from 150° C. to 250° C.

16. An insulating film obtained by the film formation method according to claim 1.
